(19) United States
(12) Patent Application Publication
(10) Pub. No.: US 2010/0112191 A1
(43) Pub. Date: May 6, 2010

(54) SYSTEMS AND ASSOCIATED METHODS FOR DEPOSITING MATERIALS

(75) Inventors: Zhe Song, Boise, ID (US); Jeffery B. Hull, Boise, ID (US); Shyam Surthi, Boise, ID (US)

Correspondence Address: PERKINS COIE LLP;PATENT-SEA, PO BOX 1247, SEATTLE, WA, 98111-1247, US

(73) Assignee: MICRON TECHNOLOGY, INC., Boise, ID (US)

(21) Appl. No.: 12/262,036

(22) Filed: Oct. 30, 2008

(51) Int. Cl. B05D 5/12; C23C 16/54

(52) U.S. Cl. 427/58; 118/710; 118/715

(57) ABSTRACT

Several embodiments of systems for depositing materials and associated methods of operation are disclosed herein. In one embodiment, the system includes a reaction chamber having an inlet and an outlet, a gas source coupled to the inlet of the reaction chamber, and a neutralizer source coupled to the outlet of the reaction chamber. The gas source contains a first precursor gas, a second precursor gas, and a purge gas. The neutralizer source contains a neutralizing agent configured to reduce a rate of reaction between the first precursor gas and the second precursor gas.

### TECHNICAL FIELD

The present disclosure is directed toward systems for depositing materials onto microelectronic workpieces and associated methods of operation.

### BACKGROUND

Atomic layer deposition (ALD) is one widely used deposition technique for depositing a material in the manufacture of microelectronic devices. FIGS. 1A and 1B schematically illustrate the basic operation of an ALD process. As illustrated in FIG. 1A, a layer of gas molecules Aₓ coats a surface of a workpiece W when the workpiece W is exposed to a first precursor. After purging with a purge gas, the workpiece W is then exposed to B_{y} molecules in a second precursor as shown in FIG. 1B. The Aₓ and B_{y} molecules then react to form a thin solid layer of material on the surface of the workpiece W.

FIG. 2 illustrates the stages of one typical cycle for forming a thin film using ALD techniques. The stages include (a) exposing the workpiece to the first precursor containing Aₓ, (b) purging excess Aₓ molecules with the purge gas, (c) exposing the workpiece to the second precursor containing B_{y}, and then (d) purging excess B_{y} molecules with the purge gas. Multiple cycles can be repeated to build a thin film having the desired thickness. For example, each cycle may form a film having a thickness of approximately 0.5-1.0 Å, and thus approximately 60-120 cycles are needed to form a film having a thickness of approximately 60 Å.

One drawback of the foregoing ALD process is that the first and second precursors tend to mix and react with each other at undesirable times and/or locations as the cycle time decreases. For example, as the purge period in FIG. 2 decreases, the first precursor may be insufficiently removed before the second precursor is injected. Thus, the first and second precursors can mix apart from the surface of the workpiece and react to form unwanted deposits on various processing components (e.g., vacuum pumps, reaction chambers, etc.) Such unwanted deposits may adversely affect the performance of the ALD process and/or shorten the lifespan of the processing components. Thus, several improvements to ALD processes may be desirable.

### BRIEF DESCRIPTION OF THE DRAWINGS

FIGS. 1A and 1B are schematic cross-sectional views of stages in atomic layer deposition processing in accordance with the prior art.

FIG. 2 is a graph illustrating a cycle for forming a layer using atomic layer deposition in accordance with the prior art.

FIG. 3 is a schematic representation of a system for depositing material onto a microelectronic workpiece in accordance with embodiments of the invention.

FIG. 4 is a schematic representation of a system having a reactor for depositing material onto a microelectronic workpiece in accordance with embodiments of the invention.

FIG. 5 is a flowchart illustrating a method for depositing material onto a microelectronic workpiece in accordance with embodiments of the invention.

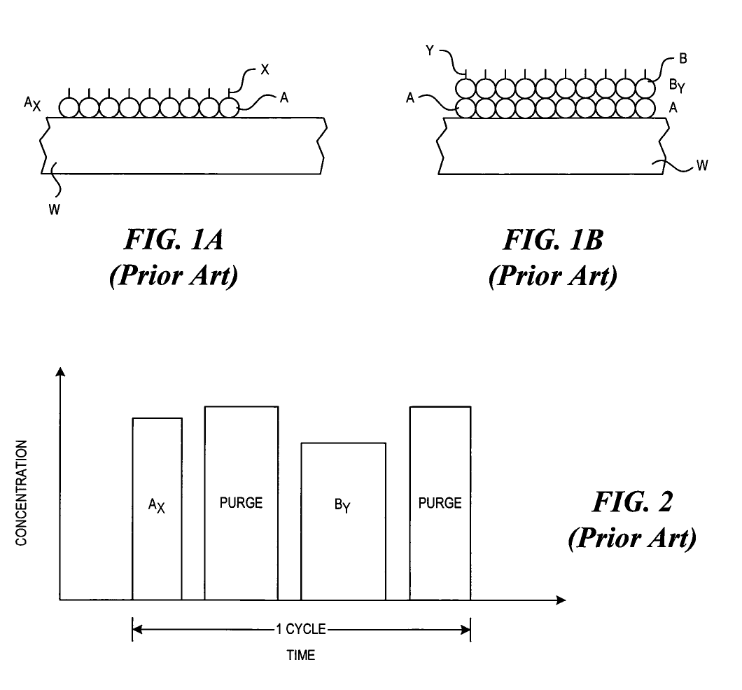

### DETAILED DESCRIPTION

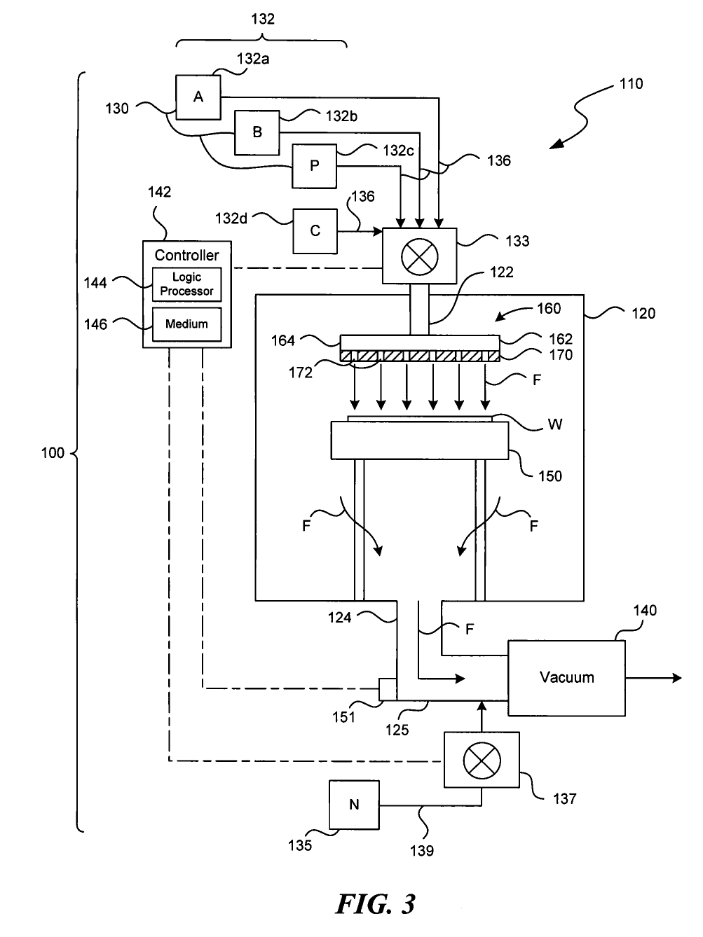

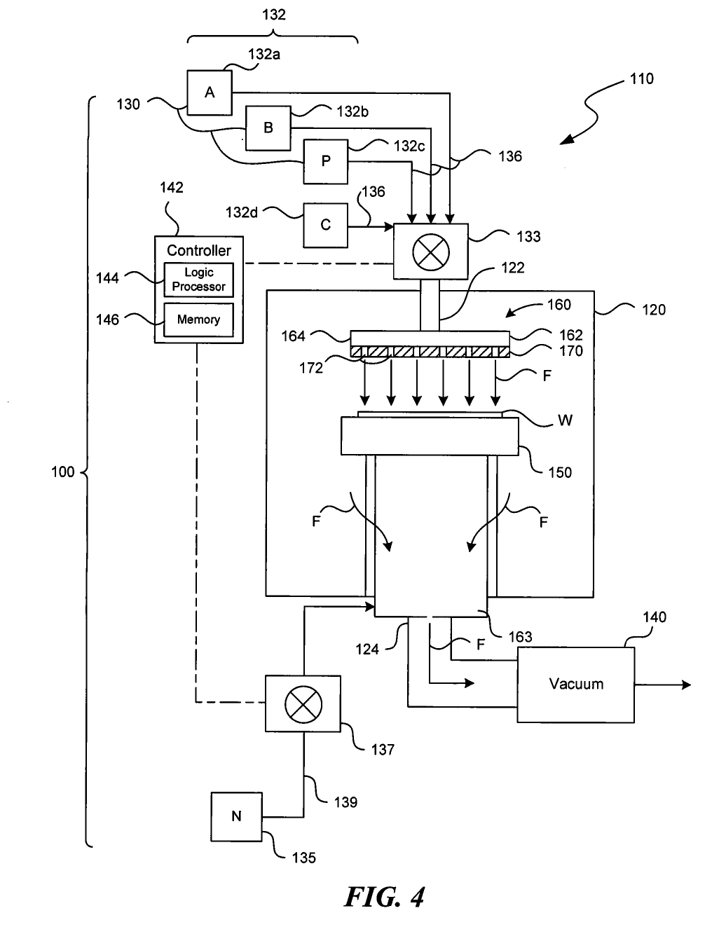

Specific details of several embodiments are described below with reference to systems for depositing material onto microelectronic workpieces and associated methods of operation. The term “microelectronic workpiece” is used throughout to include substrates upon which and/or in which microelectronic devices, micromechanical devices, data storage elements, photoelectric elements, and/or other features can be fabricated. For example, microelectronic workpieces can include semiconductor wafers, glass substrates, insulative substrates, and other types of suitable materials having SRAM, DRAM (e.g., DDR/SDRAM), flash-memory (e.g., NAND flash-memory), logic processors, CMOS imagers, CCD imagers, and other types of microelectronic device constructed thereon. The term “gas” is used throughout to include any form of matter that has no fixed shape and is conformable in volume to a space available. Although many of the embodiments are described below with respect to ALD processing systems and methods, other embodiments may include chemical vapor deposition (CVD), and/or other types of deposition systems and methods. Moreover, several embodiments of the ALD processing systems and methods can have different configurations, components, or procedures other than those described in this section. A person of ordinary skill in the art, therefore, will accordingly understand that the invention can have other embodiments with additional features, or that the invention can have other embodiments without several of the features shown and described below in reference to FIGS. 3 and 4.

FIG. 3 is a schematic representation of a system 100 for depositing material onto a microelectronic workpiece W in accordance with an embodiment of the invention. As illustrated in FIG. 3, the system 100 can include a reactor 110 coupled to a gas supply 130 and a vacuum 140 in series. The vacuum 140 can include a vacuum pump (e.g., a liquid-ring pump), a jet (e.g., a steam jet), and/or another suitable vacuum source. In other embodiments, the system 100 can also include gas scrubbers, liquid-gas separators, and/or other suitable processing components. Even though the gas supply 130 is shown in FIG. 3 as having four gas sources, in certain embodiments, the gas supply 130 can include any desired number of gas sources, which may be more or less than those shown in FIG. 3.

The reactor 110 can include a distributor 160 and a workpiece support 150 in a reaction chamber 120 with an inlet 122 and an outlet 124. The inlet 122 is coupled to the gas supply 130. The outlet 124 is coupled to the vacuum 140 via a conduit 125 (e.g., a piece of pipe or tubing). The distributor 160 faces the workpiece support 150. The distributor 160 can include a plenum 162 at least partially defined by a sidewall 164 and a distributor plate 170 with a plurality of passageways 172. The workpiece support 150 can include a plate, a vacuum chuck, a mechanical chuck, and/or another suitable supporting component. In certain embodiments, the workpiece support 150 can also include a heating element (not shown) configured to heat the workpiece W to a desired temperature. In other embodiments, the workpiece support 150 can also include other suitable components.

The gas supply 130 includes a plurality of gas sources 132, a valve assembly 133, and a plurality of gas lines 136 coupling the gas sources 132 individually to the valve assembly 133. In the illustrated embodiment, the gas sources 132 can include a first gas source 132a holding a first precursor gas “A,” a second gas source 132b holding a second precursor gas “B,” a third gas source 132c holding a purge gas “P,” and a fourth gas source 132d holding a catalyst gas “C.” The first and second precursors A and B include constituents that can react to form a solid layer of material on a surface of the microelectronic workpiece W. For example, the first precursor A can include a silicon precursor, and the second precursor B can include an oxidizer that can oxidize the silicon precursor. A suitable silicon precursor includes tris-dimethylaminosilane(((CH₃)₂N)₃SiH), tetrakis-dimethylaminosilane(((CH₃)₂N)₄Si), hexachlorodisilane(Si₂Cl₆), chlorosilane(SiCl₄), silane(SiH₄), and/or other suitable silicon precursor. A suitable oxidizer includes oxygen(O₂), ozone(O₃), hydrogen peroxide(H₂O₂), nitrous oxide(N₂O), nitric oxide(NO), dinitrogen pentoxide(N₂O₅), nitrogen dioxide(NO₂), water(H₂O), and/or other suitable oxidizing agent.

The purge gas P can include a gas that is generally inert to the reaction chamber 120 and to the workpiece W. For example, the purge gas P can include nitrogen, argon, and/or another suitable inert gas. The catalyst gas C can include compositions selected to increase a rate of reaction between the silicon precursor and the oxidizer. For example, the catalyst gas C can include ammonia(NH₃), pyridine(C₅H₅N), and/or another suitable catalytic composition. In certain embodiments, the fourth gas source 132d may be omitted, and the catalyst gas C may be combined with the first precursor gas A and/or the second precursor gas B. In further embodiments, the catalyst gas C may be omitted from the gas supply 130.

The valve assembly 133 can be configured to selectively allow a gas to flow into the reaction chamber 120 from the gas supply 130. The valve assembly 133 can include a plurality of valves, a multi-way valve, and/or other suitable flow directing components. For example, in one embodiment, the valve assembly 133 can include four single-path valves (e.g., gate valves) individually coupled to the gas sources 132. In another embodiment, the valve assembly 133 can include a multipath valve (e.g., a four-way valve) with each path coupled to the gas sources 132 individually. In other embodiments, the valve assembly 133 can include a combination of single-path valves and multipath valves and/or other suitable arrangements.

The system 100 can also include a neutralizer source 135 coupled to the outlet 124 of the reaction chamber 120 upstream of the vacuum 140 via the conduit 125 and a neutralizer valve 137 (e.g., a gate valve). The neutralizer source 135 can contain a neutralizing agent “N” selected to reduce a rate of reaction between the first and second precursor gases A and B. In one embodiment, the neutralizing agent N can contain at least one of carbon dioxide(CO₂), nitrogen oxide(NO), nitrogen dioxide(NO₂), sulfur dioxide(SO₂), hydrogen fluoride(HF), hydrogen chloride(HCl), hydrogen iodide(HI), nitrogen trifluoride(NF₃), chlorine trifluoride(ClF₃), an organic acid (e.g., formic acid or acetic acid), and/or another suitable electrophile. In another embodiment, the neutralizing agent N can include glycol, polyethylene glycol, and/or other hygroscopic substances. In further embodiments, the neutralizing agent N can include both an electrophile, a hygroscopic substance, and/or another suitable composition.

Optionally, the system 100 can include a sensor 151 upstream of the vacuum 140. The sensor 151 can be configured to monitor a concentration and/or other characteristics of at least one of the first precursor gas A, the second precursor gas B, and/or the catalyst gas C. In one embodiment, the sensor 151 includes a pH monitor. In other embodiments, the sensor 151 can also include a mass spectrometer, a UV-visible spectrometer, an infrared radiation spectrometer, a gas chromatography analyzer, and/or other suitable chemical analyzers. In the illustrated embodiment, the sensor 151 is approximate to the conduit 125. In other embodiments, the sensor 151 can be approximate to the reaction chamber 120, the vacuum 140, and/or other components of the system 100.

The system 100 can also include a controller 142 electrically coupled to the valve assembly 133, the neutralizer valve 137, and the optional sensor 151. The controller 142 can include a logic processor 144 coupled to a computer-readable medium 146 having computer-executable instructions stored therein. The logic processor 144 can include a microprocessor, a digital signal processor, and/or other suitable processing components. The computer-readable medium 146 can include any mechanism that provides (i.e., stores and/or transmits) information in a form accessible by the logic processor 144. In one embodiment, the computer-readable medium 146 includes volatile and/or nonvolatile media (e.g., read-only memory (ROM); random access memory (RAM); magnetic disk storage media; optical storage media; flash memory devices; etc.) The controller 142 can also include specific hardware components having hard-wired logic (e.g., field-programmable gate arrays) for performing the operations, methods, or processes or with any combination of programmed data processing components and specific hardware components.

The computer-executable instructions can be configured to cause the logic processor 144 to perform methods or processes in accordance with embodiments of the system 100. For example, the computer-executable instructions can cause the logic processor 144 to generate signals for pulsing the individual gases through the reaction chamber 120 in a number of cycles. Each cycle can include a first pulse of the first precursor gas A, a second pulse of the purge gas P, a third pulse of the second precursor gas B, and a fourth pulse of the purge gas P. The computer-executable instructions can also cause the logic processor 144 to inject the neutralizing agent N into an exhaust of the reaction chamber 120 during at least a portion of the deposition process. The computer-executable instructions can also cause the logic processor 144 to monitor a process parameter via the optional sensor 151 and adjust the flow of the neutralizing agent N based on the monitored process parameter. Various operations, methods, or processes performed by the controller 142 are described in more detailed below.

During a deposition process, in certain embodiments, the controller 142 can first command the valve assembly 133 to selectively flow the first precursor gas A and the catalyst gas C into the reaction chamber 120 via the inlet 122. The first precursor gas A and the catalyst gas C then flow into the distributor 160 to be dispensed onto the surface of the microelectronic workpiece W. As a result, a layer of the first precursor gas A and the catalyst gas C can be adsorbed and/or otherwise attached to the surface of the microelectronic workpiece W. The vacuum 140 exhausts excess first precursor gas A and the catalyst gas C from the reaction chamber 120 along a flow path “F.”

After a first deposition period (e.g., 10 seconds), the controller 142 can command the valve assembly 133 to stop the flow of the first precursor gas A and the catalyst gas C and start to flow the purge gas P into the reaction chamber 120. The flow of the purge gas P can continue for a first purge period (e.g., 10 seconds) sufficient to reduce the concentration of the first precursor gas A and the catalyst gas C in the reaction chamber 120 to a desired level.

After the first purge period, the controller 142 can then command the valve assembly 133 to selectively flow the second precursor gas B and the catalyst gas C into the reaction chamber 120 via the inlet 122. The second precursor gas B and the catalyst gas C then flow into the distributor 160 to be dispensed onto the surface of the microelectronic workpiece W. As a result, a layer of the second precursor gas B and the catalyst gas C can be adsorbed and/or otherwise attached to the layer of the first precursor gas A and/or the surface of the microelectronic workpiece W. The vacuum 140 exhausts excess second precursor gas B and the catalyst gas C from the reaction chamber 120 along flow path F.

Components of the first and second precursor gases A and B can then react to produce a thin film in the presence of the catalyst gas C. For example, in one embodiment, the first precursor gas A containing hexachlorodisilane can react with the second precursor gas B containing water in the presence of the catalyst gas C containing pyridine to produce a silicon oxide(SiO₂) film as follows:

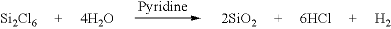

In other embodiments, the first and/or second precursor gases A and B can contain other suitable precursor compositions to produce a film of polysilicon(Si), silicon nitride(SiNe), metal (e.g., Cu, Al, W, etc.), and/or another desired material.

After a second deposition period (e.g., 10 seconds), the controller 142 can command the valve assembly 133 to stop the flow of the second precursor gas B and the catalyst gas C and again start to flow the purge gas P into the reaction chamber 120. The flow of the purge gas P can continue for a second purge period (e.g., 10 seconds) sufficient to reduce the concentration of the second precursor gas B and the catalyst gas C in the reaction chamber 120 to a desired level. Then, controller 142 can repeat the deposition cycle by selectively flowing the first precursor gas A and the catalyst gas C into the reaction chamber 120 via the inlet 122 until a desired deposition is achieved on the surface of the microelectronic workpiece W.

In any of the foregoing embodiments, the controller 142 can command the neutralizer valve 137 to flow the neutralizing agent N into the conduit 125 during at least a portion of the deposition process. In one embodiment, the flow of the neutralizing agent N can be generally continuous for the entire duration of the deposition process. In other embodiments, the flow of the neutralizing agent N can be based on a temporal relationship between the flow of the first precursor gas A, the second precursor gas B, and/or the purge gas P. For example, the neutralizing agent N can be flowed before, substantially contemporaneous with, or after a delay period (e.g., 10 seconds) following the flowing of the first and second precursor gases A and B into the reaction chamber 120.

In further embodiments, the flow of the neutralizing agent N can be at least in part based on a process parameter of the deposition process. For example, the controller 142 can monitor a concentration of the catalyst gas C in the conduit 125 via the sensor 151. If the monitored concentration is above a predetermined threshold, the controller 142 can open the neutralizer valve 137 to flow the neutralizing agent N into the conduit 125 at a first rate; or, the controller 142 can either stop the flow of the neutralizing agent N or maintain the flow of the neutralizing agent N at a second rate lower than the first rate. In other examples, the controller 142 can also monitor and control the flow of the neutralizing agent N based on the concentration of the first precursor gas A, the second precursor gas B, the purge gas P, the deposition rate on the conduit 125, and/or other suitable process parameters. In yet further embodiments, the flow of the neutralizing agent N can be based on a combination of a temporal relationship and a monitored process parameter.

The neutralizing agent N can then mix with the first precursor gas A, the second precursor gas B, and the catalyst gas C exiting the reaction chamber 120 upstream of the vacuum 140. In certain embodiments, the neutralizing agent N can poison the catalyst gas C. For example, the neutralizing agent N can react and/or otherwise combine with the catalyst gas C to at least reduce its catalytic effectiveness. Without being bound by theory, in a particular embodiment, it is believed that a neutralizing agent N containing hydrogen fluoride(HF) can react with a catalyst gas C containing pyridine(C₅H₅N) to remove the lone electron pair of pyridine as follows:

C₅H₅N+HF→C₅H₆N⁺+F⁻

It is also believed that without the lone electron pair, the catalyst gas C is ineffective in facilitating the reaction between the first and second precursor gases A and B. As a consequence, the activation energy of the reaction between the first and second precursor gases A and B increases. Accordingly, the concentration of the catalyst gas C and the rate of reaction between the first and second precursor gases A and B both decrease away from the workpiece support 150 without affecting the deposition of the layer of solid material on the surface of the microelectronic workpiece W.

In other embodiments, the neutralizing agent N can also reduce a concentration of the first and/or second precursor gases A and B. For example, the neutralizing agent N can absorb, adsorb, chemically react, and/or otherwise combine with the first and/or second precursor gases A and B. In a particular example, the first and second precursor gases A and B include hexachlorodisilane and water, respectively, and the neutralizing agent N includes glycol that can absorb water. Thus, the concentration of the second precursor gas B can be reduced to decrease the rate of reaction between hexachlorodisilane and water.

Several embodiments of the system 100 can have improved deposition efficiency and/or components with longer lifespans than in conventional systems. The inventors have recognized that as the cycle time decreases in an ALD process, the first and second precursor gases A and B can coexist in the exhaust of the reaction chamber 120. As a result, the first and second precursor gases A and B can react to deposit an unwanted layer of solid material (e.g., SiO₂) on internal components of the vacuum 140 and/or other processing components downstream of the workpiece support 150. Such unwanted deposition can adversely affect the performance of the system 100 by reducing a suction head of the vacuum 140 and/or shortening the lifespan of the vacuum 140. As a result, by flowing the neutralizing agent N into the exhaust upstream of the vacuum 140, the rate of reaction between the first and second precursor gases A and B can be reduced. The reduced reaction rate can at least reduce solid deposition on internal components of the vacuum 140, and thus prolong its life.

Although the system 100 is illustrated in FIG. 3 as being configured to process a single microelectronic workpiece W, in other embodiments, the system 100 may be configured to process multiple microelectronic workpieces, e.g., by having a wafer boat designed to carry multiple microelectronic workpieces. In other embodiments, the first precursor gas A, the second precursor gas B, and the catalyst gas C can be flowed into the reaction chamber 120 individually. For example, a flow of the catalyst gas C can follow a flow of the first precursor gas A and/or the second precursor gas B. In further embodiments, the flow of the catalyst gas C can be omitted, or the catalyst gas C can be combined with the first and/or second precursor gases A and B in the first and second gas sources 132a and 132b, respectively.

Even though the system 100 illustrated in FIG. 3 has the neutralizer source 135 coupled to the conduit 125, in other embodiments, the neutralizer source 135 can also be coupled directly to the reaction chamber 120. For example, as illustrated in FIG. 4, the reaction chamber 120 can include an outlet plenum 163 between the workpiece support 150 and the outlet 124, and the neutralizer valve 137 can couple the neutralizer source 135 to the outlet plenum 163. In other embodiments, the neutralizer source 135 can also be coupled to the vacuum 140 and/or other processing components of the system 100.

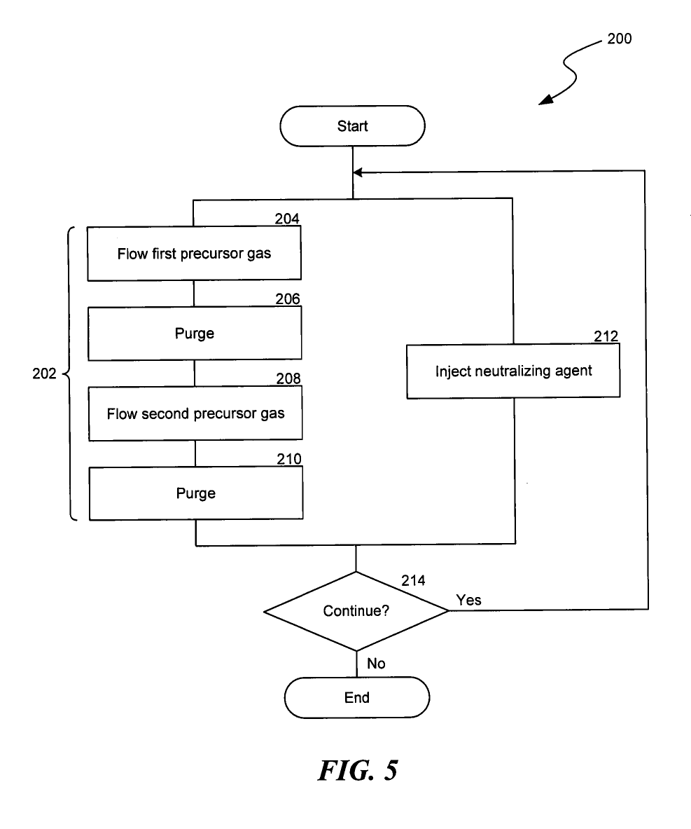

Several embodiments of a deposition process 200 are illustrated in FIG. 5. Even though the embodiments of the deposition process 200 are discussed below with reference to the system 100 of FIG. 3, one skilled in the art will understand that certain embodiments of the deposition process 200 can also be practiced in systems with different and/or additional process components.

As shown in FIG. 5, the deposition process 200 can include deposition stages 202 in which a first precursor gas and a second precursor gas are sequentially or alternatively injected into a reaction chamber with purging stages therebetween. For example, the deposition stages 202 can include sequentially flowing the first precursor gas into the reaction chamber 120 (FIG. 3) for a first deposition period to contact the surface of the microelectronic workpiece W (stage 204), purging the reaction chamber for a first purge period (stage 206), flowing the second precursor gas for a second deposition period to contact the surface of the microelectronic workpiece W (stage 208), and purging the reaction chamber for a second purge period (stage 210). In certain embodiments, the deposition stages 202 can also include flowing a catalyst gas into the reaction chamber 120 with the first and/or second precursor gases. In other embodiments, the deposition stages 202 can also include flowing the catalyst gas before flowing the first and second precursor gases. In further embodiments, the catalyst gas can be omitted.

The deposition process 200 can also include an injection stage 212 in which a neutralizing agent is injected into the reaction chamber away from the surface of the microelectronic workpiece W. The neutralizing agent is selected to reduce a rate of reaction between the first and second precursor gases, as described above with reference to FIG. 3. In the illustrated embodiment, the injection stage 212 is generally contemporaneous with the deposition stages 202. In other embodiments, the injection stage 212 can have an on-delay and/or an off-delay from the deposition stages 202. In further embodiments, the injection stage 212 can correspond with only a limited number of deposition stages 202. In one example, the injection stage 212 corresponds only with the purging of the reaction chamber 120 at stages 206 and 210. In other examples, the injection stage 212 corresponds with the flowing of the first and second precursor gases at stages 204 and 208.

The deposition process 200 can include a decision block 214 to determine whether the process should continue. Conditions for continuing the process can include an insufficient deposition on the surface of the microelectronic workpiece W, and/or other suitable conditions. If the process continues, the process reverts to flowing the first precursor gas at stage 204 and injecting the neutralizing agent at stage 212; otherwise, the process ends.

From the foregoing description, it will be appreciated that specific embodiments of the invention have been described herein for purposes of illustration, but that various modifications may be made without deviating from the invention. For example, many of the elements of one embodiment may be combined with other embodiments in addition to or in lieu of the elements of the other embodiments. Accordingly, the invention is not limited except as by the appended claims.

We claim:

1. A system for depositing a material onto a microelectronic workpiece, comprising:
a reaction chamber having an inlet and an outlet;
a gas source containing a first precursor gas, a second precursor gas, and a purge gas, the first and second precursor gases being configured to react with each other to produce a material on a surface of the microelectronic workpiece;
a valve assembly coupling the gas source to the inlet of the reaction chamber;
a vacuum coupled to the outlet of the reaction chamber;
a neutralizer source containing a neutralizing agent configured to reduce a rate of reaction between the first precursor gas and the second precursor gas;
a neutralizer valve coupling the neutralizer source to the outlet of the reaction chamber; and
a controller operably coupled to the valve assembly and the neutralizer valve, the controller having a computer-readable medium containing instructions that cause the controller to flow the neutralizer agent into the outlet of the reaction chamber during at least a portion of a deposition process.

2. The system of claim 1 wherein
the gas source also contains a catalyst gas configured to catalyze a reaction between the first and second precursor gases, the catalyst gas including at least one of ammonia(NH₃) and pyridine(C₅H₅N);
and wherein the neutralizing agent contains at least one of carbon dioxide(CO₂), nitrogen oxide(NO), nitrogen dioxide(NO₂), sulfur dioxide(SO₂), hydrogen fluoride(HF), hydrogen chloride(HCl), hydrogen iodide(HI), nitrogen trifluoride(NF₃), chlorine trifluoride(CIF₃), and an organic acid;
and wherein the computer-readable medium contains instructions that cause the controller to perform a method comprising:
flowing the first precursor gas and the catalyst gas into the reaction chamber via the valve assembly for a first deposition period;
stopping a flow of the first precursor gas and the catalyst gas after the first deposition period expires;
purging the reaction chamber with the purge gas for a first purge period;
flowing the second precursor gas and the catalyst gas into the reaction chamber via the valve assembly for a second deposition period after the first purge period expires;
purging the reaction chamber with the purge gas for a second purge period after the second period expires; and
continuously flowing the neutralizer agent into the outlet of the reaction chamber during at least the first deposition period, the first purge period, the second deposition period, and the second purge period.

3. The system of claim 1 wherein
the gas source also contains a catalyst gas configured to catalyze a reaction between the first and second precursor gases, the catalyst gas including at least one of ammonia(NH₃) and pyridine(C₅H₅N);
and wherein the neutralizing agent contains at least one of carbon dioxide(CO₂), nitrogen oxide(NO), nitrogen dioxide(NO₂), sulfur dioxide(SO₂), hydrogen fluoride(HF), hydrogen chloride(HCl), hydrogen iodide(HI), nitrogen trifluoride(NF₃), chlorine trifluoride(CIF₃), and an organic acid;
and wherein the computer-readable medium contains instructions that cause the controller to perform a method comprising:
flowing the first precursor gas and the catalyst gas into the reaction chamber via the valve assembly for a first deposition period;
stopping a flow of the first precursor gas and the catalyst gas after the first deposition period expires;
purging the reaction chamber with the purge gas for a first purge period;
flowing the second precursor gas and the catalyst gas into the reaction chamber via the valve assembly for a second deposition period after the first purge period expires;
purging the reaction chamber with the purge gas for a second purge period after the second period expires;
flowing the neutralizer agent into the outlet of the reaction chamber during the first deposition period and the second deposition period; and
stopping a flow of the neutralizer agent into the outlet of the reaction chamber during the first purge period and the second purge period.

4. The system of claim 1 wherein the computer-readable medium contains instructions that cause the controller to monitor a process parameter of the deposition process and to adjust the flow of the neutralizing agent based on the monitored process parameter.

5. The system of claim 1 wherein
the gas source also contains a catalyst gas configured to catalyze a reaction between the first and second precursor gases, the catalyst gas including at least one of ammonia(NH₃) and pyridine(C₅H₅N);
and wherein the neutralizing agent contains at least one of carbon dioxide(CO₂), nitrogen oxide(NO), nitrogen dioxide(NO₂), sulfur dioxide(SO₂), hydrogen fluoride(HF), hydrogen chloride(HCl), hydrogen iodide(HI), nitrogen trifluoride(NF₃), chlorine trifluoride(CIF₃), and an organic acid;
and wherein the computer-readable medium contains instructions that cause the controller to monitor a concentration of at least one of the first precursor gas, the second precursor gas, and the catalyst gas proximate to the outlet of the reaction chamber and to adjust the flow of the neutralizing agent based on the monitored concentration.

6. The system of claim 1 wherein the computer-readable medium contains instructions that cause the controller to monitor a value of at least one of a pH level, a mass spectrum, a UV-visible spectrum, and an infrared radiation spectrum proximate to the outlet of the reaction chamber and to adjust the flow of the neutralizing agent based on the monitored value.

7. The system of claim 1 wherein the computer-readable medium contains instructions that cause the controller to perform a method comprising:
monitoring a process parameter of the deposition process;
if the monitored process parameter is above a predetermined threshold, flowing the neutralizing agent at a first rate; or
if not, flowing the neutralizing agent at a second rate lower than the first rate.

8. The system of claim 1 wherein the computer-readable medium contains instructions that cause the controller to perform a method comprising:
monitoring a process parameter of the deposition process;
if the monitored process parameter is above a predetermined threshold, flowing the neutralizing agent at a first rate; or
if not, stopping a flow of the neutralizing agent.

9. A system for depositing a material onto a microelectronic workpiece, comprising:
a reaction chamber having an inlet and an outlet;
a gas source coupled to the inlet of the reaction chamber, the gas source containing a first precursor gas, a second precursor gas, a catalyst gas, and a purge gas; and
a neutralizer source coupled to the outlet of the reaction chamber, the neutralizer source containing a neutralizing agent configured to reduce catalytic effectiveness of the catalyst gas in facilitating a reaction between the first and second precursor gases.

10. The system of claim 9 wherein the neutralizing agent is configured to reduce a concentration of the catalyst gas at the outlet of the reaction chamber.

11. The system of claim 9 wherein the neutralizing agent is configured to reduce the catalytic effectiveness of the catalyst gas and a concentration of at least one of the first and second precursor gases at the outlet of the reaction chamber.

12. The system of claim 9 wherein the neutralizing agent is configured to chemically react with the catalyst gas and render the catalyst gas ineffective in facilitating the reaction between the first and second precursor gases.

13. The system of claim 1 wherein the catalyst gas contains a nucleophile, and wherein the neutralizing agent contains an electrophile reactive to the nucleophile.

14. A method for depositing a material onto a microelectronic workpiece comprising:
supporting the microelectronic workpiece on a workpiece support in a reaction chamber;
sequentially contacting a surface of the microelectronic workpiece with a first precursor gas and a second precursor gas;
reacting the first and second precursor gases to deposit a material film on the surface of the microelectronic workpiece; and
reducing a rate of reaction between the first and second precursor gases away from the surface of the microelectronic workpiece.

15. The method of claim 14 wherein reducing a rate of reaction includes reducing the rate of reaction between the first and second precursor gases without affecting depositing the material film on the surface of the microelectronic workpiece.

16. The method of claim 14, further comprising contacting the surface of the microelectronic workpiece with a catalyst gas configured to catalyze a reaction between the first and second precursor gases, wherein reducing a rate of reaction includes poisoning the catalyst gas away from the workpiece support.

17. The method of claim 14, further comprising contacting the surface of the microelectronic workpiece with a catalyst gas configured to catalyze a reaction between the first and second precursor gases, wherein the catalyst gas includes pyridine(C₅H₅N), and wherein reducing a rate of reaction includes reacting the catalyst gas with an electrophile and removing a lone electron pair from pyridine in the catalyst gas.

18. The method of claim 14, further comprising contacting the surface of the microelectronic workpiece with a catalyst gas configured to catalyze a reaction between the first and second precursor gases, wherein the catalyst gas includes pyridine(C₅H₅N), and wherein reducing a rate of reaction includes reacting pyridine in the catalyst gas with at least one of carbon dioxide(CO₂), nitrogen oxide(NO), nitrogen dioxide(NO₂), sulfur dioxide(SO₂), hydrogen fluoride(HF), hydrogen chloride(HCl), hydrogen iodide(HI), nitrogen trifluoride(NF₃), chlorine trifluoride(ClF₃), and an organic acid.

19. The method of claim 14, further comprising contacting the surface of the microelectronic workpiece with a catalyst gas configured to catalyze a reaction between the first and second precursor gases, wherein the catalyst gas includes pyridine(C₅H₅N), and wherein reducing a rate of reaction includes oxidizing pyridine in the catalyst gas and at least reducing catalytic effectiveness of the catalyst gas.

20. The method of claim 14, further comprising contacting the surface of the microelectronic workpiece with a catalyst gas configured to catalyze a reaction between the first and second precursor gases, wherein the catalyst gas includes pyridine(C₅H₅N), and wherein reducing a rate of reaction includes reacting the catalyst gas with hydrogen fluoride and removing a lone electron pair from pyridine in the catalyst gas as follows:
C₅H₅N+HF→C₅H₆N⁺+F⁻

21. A method for depositing a material onto a microelectronic workpiece, comprising:
flowing a first precursor gas into an inlet of a reaction chamber, past a surface of the microelectronic workpiece, and out of an outlet of the reaction chamber;
separately flowing a second precursor gas into the inlet of the reaction chamber, past the surface of the microelectronic workpiece, and out of the outlet of the reaction chamber, the first and second precursor gases being configured to form a material film on the surface of the microelectronic workpiece; and
injecting a neutralizing gas downstream of the surface of the microelectronic workpiece, the neutralizing gas being configured to reduce a rate of reaction between the first and second precursor gases.

22. The method of claim 21 wherein injecting a neutralizing gas includes maintaining a continuous flow rate of the neutralizing gas while flowing the first precursor gas and separately flowing the second precursor gas.

23. The method of claim 21, further comprising:
flowing a catalyst gas into the reaction chamber, the catalyst gas being configured to facilitate a reaction between the first and second precursor gases; and
mixing the neutralizing gas with the catalyst gas downstream of the surface of the microelectronic workpiece, the neutralizing gas being configured to reduce catalytic effectiveness of the catalyst gas.

24. The method of claim 21, further comprising:
flowing a catalyst gas into the reaction chamber, the catalyst gas being configured to facilitate a reaction between the first and second precursor gases; and
mixing the neutralizing gas with the catalyst gas in an outlet plenum of the reaction chamber, the neutralizing gas being configured to reduce catalytic effectiveness of the catalyst gas.

25. The method of claim 21, further comprising:
flowing a catalyst gas into the reaction chamber, the catalyst gas being configured to facilitate a reaction between the first and second precursor gases;
evacuating the first and second precursor gases and the catalyst gas from the reaction chamber with a vacuum; and
mixing the neutralizing gas with the catalyst gas downstream of the surface of the microelectronic workpiece and upstream of the vacuum, the neutralizing gas being configured to reduce catalytic effectiveness of the catalyst gas.

26. A system for depositing a material onto a microelectronic workpiece, comprising:
a reaction chamber;
a gas source containing a silicon precursor gas, an oxidizer gas, and a purge gas;
a valve assembly coupling the gas source to the reaction chamber for alternatively supplying the first and second precursor gases to a surface of the microelectronic workpiece; and
means for reducing a rate of reaction between the silicon precursor gas and the oxidizer gas away from the surface of the microelectronic workpiece.

27. The system of claim 26 wherein the means for reducing a rate of reaction include means for increasing an activation energy of a reaction between the silicon precursor gas and the oxidizer gas away from the surface of the microelectronic workpiece.

28. The system of claim 26 wherein the gas source also includes a catalyst gas, and wherein the means for reducing a rate of reaction include means for neutralizing the catalyst gas away from the surface of the microelectronic workpiece.

29. The system of claim 26 wherein the gas source also includes a catalyst gas, and wherein the means for reducing a rate of reaction include means for oxidizing the catalyst gas away from the surface of the microelectronic workpiece.
